(19) United States
(12) Patent Application Publication
(10) Pub. No.: US 2026/0209032 A1
(43) Pub. Date: Jul. 23, 2026

(54) MEMS COMPONENT AND METHOD FOR PRODUCING A MEMS COMPONENT

(71) Applicant: Robert Bosch GmbH, Stuttgart (DE)

(72) Inventors: Leo Rizzi, Reutlingen (DE); Johannes Boy, Moessingen (DE)

(21) Appl. No.: 19/448,211

(22) Filed: Jan. 14, 2026

(30) Foreign Application Priority Data
Jan. 20, 2025 (DE) 10 2025 101 821.9

(51) Int. Cl. B81B 7/00; B81C 1/00

(52) U.S. Cl. CPC B81B 7/008; B81B 7/0061; B81C 1/00238; B81B 2201/0228

(57) ABSTRACT

A MEMS component. The MEMS component includes a substrate with a front side and a rear side, a MEMS functional unit arranged on the front side of the substrate, an electrical circuit unit arranged on the rear side of the substrate for applying, receiving and/or processing signals of the MEMS functional unit, and an electrical connection structure extending through the substrate for electrically connecting the MEMS functional unit to the electrical circuit unit. A method for producing such a MEMS component is also described.

### CROSS REFERENCE

The present application claims the benefit under 35 U.S.C. § 119 of Germany Patent Application No. DE 10 2025 101 821.9 filed on January 20, 2025, which is expressly incorporated herein by reference in its entirety.

### FIELD

The present disclosure relates to a MEMS component and to a method for producing it.

### BACKGROUND INFORMATION

MEMS components and methods for their production are described in the related art. The abbreviation MEMS stands for microelectromechanical systems, which, through microstructural properties and suitable production processes, make it possible to miniaturize electromechanical functional components such as actuators and sensors.

Germany Patent Application No. DE 10 2007 048 604 A1 describes a composite consisting of a first semiconductor substrate with a MEMS component and a second semiconductor substrate which may comprise an ASIC component. The first semiconductor substrate and the second semiconductor substrate are eutectically connected to each other by a germanium-containing layer and an aluminum-containing layer.

### SUMMARY

According to the features of an example embodiment of the present disclosure, a MEMS component is provided, which comprises a substrate with a front side and a rear side, a MEMS functional unit arranged on the front side of the substrate, an electrical circuit unit arranged on the rear side of the substrate for applying, receiving and/or processing signals of the MEMS functional unit, and an electrical connection structure extending through the substrate for electrically connecting the MEMS functional unit to the electrical circuit unit.

In simplified terms, a monolithic component concept is proposed, in which, for forming a MEMS component, a microelectromechanical functional unit and an associated control and/or evaluation circuit are arranged on two different sides of a substrate and are connected to each other by at least one electrical line extending through the substrate. This makes it easy to reduce the component size of a MEMS component with a MEMS functional unit and an associated circuit unit. Furthermore, the MEMS component can be produced cost-effectively. For example, a further substrate as a support structure for the circuit unit can be omitted.

Furthermore, largely independent processing of the MEMS functional unit and the circuit unit on different substrate sides is made possible during the production of the MEMS component so that, for example, the processing of the MEMS functional unit is unaffected by a temperature sensitivity and stress generation tendency of metal or non-metal structures of the circuit unit on the opposite substrate side, and high-temperature processes can be used. Furthermore, layer structures for forming the MEMS functional unit and the circuit unit can be optimized independently of each other.

In principle, a MEMS component can be a component produced using semiconductor technology and, due to its microstructural design, can be suitable for implementation as a system-on-chip (SoC). The MEMS functional unit can be a structural and functional unit of the MEMS component with mechanical and electrical microstructures that can be used to implement mechanical, physical and/or chemical component functions, for example. The MEMS functional unit can be configured, for example, as an electromechanical transducer in order to convert electrical signals into mechanical power of a MEMS functional element or to convert mechanical interactions of a MEMS functional element with an environment of the MEMS component into electrical signals.

The substrate can be a planar semiconductor support structure. The substrate can be a silicon wafer, for example. The substrate has two mutually opposite substrate surfaces, which are referred to as a front side and a rear side. The front side of the substrate can form a so-called active side of the substrate, on which side the microstructures of the MEMS functional unit are arranged. With regard to the proposed MEMS component, the substrate can fulfill a mechanical support function and an electrical connection function with respect to the MEMS functional unit and the circuit unit.

According to an example embodiment, the electrical circuit unit is configured to apply, receive and/or process signals of the MEMS functional unit, and can therefore be control and/or evaluation electronics of the MEMS functional unit. The circuit unit can be designed in particular as a so-called integrated circuit (IC). The circuit unit can have a plurality of circuit planes, which can be arranged in layers one above the other. Circuit components of the circuit unit, such as conductor tracks, connection points, or electronic components, can be produced by means of metal and/or semiconductor-based material layers, for example. The circuit components can be isolated from one another by dielectric material layer regions. The circuit unit can have a so-called front-end plane, which faces the substrate, and a back-end plane, which faces away from the substrate and can provide an external electrical contact option for the circuit unit.

In simplified terms, the electrical connection structure extending through the substrate can have one or more electrical lines that extend through the substrate and contact electrical connection structures on the MEMS functional unit and on the circuit unit. The electrical connection structure can extend in particular substantially vertically, i.e., perpendicularly to a substrate surface of the substrate. The connection structure can, for example, comprise one or more TSV (through-silicon via) connections, which are also referred to as silicon vias in practice and describe a mostly vertical electrical metal connection through a silicon wafer in semiconductor technology.

According to one example embodiment, the MEMS component can additionally comprise a cap and a side frame, which, together with the substrate, enclose a cavity, in which the MEMS functional unit is arranged. This allows the MEMS functional unit to be arranged in a way that protects it from mechanical forces and environmental influences. The side frame can act as a spacer so that the cap is at a distance from the MEMS functional unit and does not impair its function. Moreover, by functioning as a spacer, the side frame can define a desired cavity volume in which the MEMS functional unit is located. The cap may comprise a further substrate or be made from a further substrate. The cap can have a silicon-based structure. The further substrate can be a silicon wafer, for example. However, the further substrate can also include an electrically active layer structure, in particular an integrated circuit. The cap can be configured in particular to seal the cavity of the MEMS component in a gas-tight manner when a gas or gas mixture at a predefined internal pressure is enclosed in the cavity, as explained in more detail below. The cap can be connected via a wafer bond connection to the substrate in the region of the side frame. The wafer bond connection can, for example, be based on an aluminum-germanium connection and be designed as a eutectic wafer bond connection. A hermetic seal of the cavity can be easily realized by means of a wafer bond connection. Since the circuit unit of the MEMS component is arranged on a side of the substrate facing away from the cavity, a robust cap with a purely mechanical or predominantly mechanical function can be used, which can be designed, for example, as a structured silicon wafer and, together with the wafer bond connection, forms a robust, tight seal of the cavity. However, a cap with a predominantly mechanical function does not fundamentally preclude the possibility of arranging an electrically active structure in the cap. This structure can, for example, be laid in a cap interior without surface contact to the adjacent cavity through the cap and be separated from the cap, for example, by a continuous silicon layer.

According to one possible example embodiment, the MEMS component can also have a plurality of, i.e., two or more, spatially separated cavities, each with a MEMS functional unit arranged therein. This allows, for example, a plurality of similar and/or different MEMS functional units to be operated in a common MEMS component.

According to one example embodiment, a gas or gas mixture at a predefined internal pressure can be enclosed in the cavity. This allows the damping properties of the MEMS functional unit to be influenced in a targeted manner, for example. This can be advantageous, for example, when the MEMS component is used to detect accelerations or rotation rates. By being able to use a simple mechanical cap to cover the MEMS functional unit and by arranging the circuit unit on a side of the substrate facing away from the cavity, hydrogen outgassing into the cavity, which is associated with certain dielectrics, can be prevented or at least minimized so that a preset internal pressure in the cavity can be maintained in a long-term stable manner. This allows for greater freedom of design, including in terms of material selection during the production of the circuit unit. The electrical connection structure between the MEMS functional unit and the circuit unit can be designed, through suitable material selection and dimensioning, in such a way that it can be considered to be gas-impermeable, so that impairment of the cavity’s internal pressure by gas ingress or egress via the electrical connection structure can be substantially excluded. For example, the electrical connection structure can have a minimum length of 300 µm.

According to one example embodiment, an access channel for a fluidic connection of the cavity to an environment of the MEMS component can be arranged in the cap and/or in the side frame. The MEMS functional unit is thus configured to interact with the environment and can be used, for example, to detect a property such as ambient pressure or for gas analysis of a gas or gas mixture present in the environment. By arranging the circuit unit on a side of the substrate facing away from the cavity, the circuit unit is protected from environmental influences by the substrate.

According to one example embodiment, an insulating layer with an electrical connection structure can be arranged on a side of the electrical circuit unit facing away from the substrate. This ensures that the electrical circuit unit is mechanically protected and electrically isolated from the environment. The insulating layer can form a cover layer of a layer structure, comprising the electrical switching unit, on the rear side of the substrate. The electrical connection structure allows the electrical circuit unit to be contacted from the outside. The electrical connection structure can, for example, be metal and extend substantially vertically, i.e., perpendicularly to a substrate surface of the substrate, through the insulating layer. The electrical connection structure can, for example, transition into solder balls arranged on the insulating layer.

According to one example embodiment, the MEMS component can be designed as a sensor component. For example, the MEMS component can be configured to detect environmental conditions or forces such as linear and/or rotational acceleration forces. By spatially separating the MEMS functional unit from the circuit unit by means of the substrate, a sensory functional region and a control-related functional region of the MEMS component can be optimized independently of each other so that high sensor accuracy and improved long-term stability can inter alia be achieved. At the same time, the monolithic design, utilizing both sides of the substrate, results in a compact and cost-effective sensor component. However, in principle, applications in which the MEMS component is designed as an actuator component are also possible. An example of such an actuator component could be a microfluidic or loudspeaker component that has a MEMS functional unit designed as a displacer unit.

According to one example embodiment, the MEMS component can be designed as an inertial sensor component. The inertial sensor component can, for example, be designed to detect linear or rotational accelerations. The inertial sensor component can therefore be used, for example, as an acceleration or rotation rate sensor. The inertial sensor component can, for example, comprise a MEMS functional unit with a seismic mass or a rotor mass and a detection unit for detecting an acceleration effect on the seismic mass or the rotor mass. In an inertial sensor, a gas or gas mixture at a predefined internal pressure can be enclosed in a cavity of the MEMS component, for example in order to be able to adjust the damping of the seismic mass or of the rotor mass. The robust embodiment of the MEMS component described above, in which a simple mechanical cap can be used to seal the cavity and in which the circuit unit does not affect the internal pressure in the cavity due to the spatial separation, allows for the provision of a high-performance and robust compact inertial sensor component.

According to one example embodiment, the MEMS component can be designed as an environmental sensor component. This allows environmental conditions to be detected with the MEMS component. Such environmental conditions can refer, for example, to a pressure, temperature, humidity, or gas composition of the component environment. The environmental sensor component can be used, for example, as a pressure or gas sensor. In an environmental sensor component, an access channel for a fluidic connection of a cavity of the MEMS component to an environment of the MEMS component can be arranged in a cap and/or in a side frame of the MEMS component. By arranging the circuit unit on a side of the substrate facing away from the cavity, interaction of the circuit unit with the component environment can be minimized.

According to one example embodiment, the MEMS component can comprise a bending compensation layer. This can reduce mechanical stress in the MEMS component, which can be caused, for example, during the production of the component due to high-temperature processes and/or materials with different coefficients of expansion. A bending compensation layer can be a material layer or a material layer combination provided to eliminate mechanical stress effects on the MEMS component. For example, a bending compensation layer may be arranged on a rear side of the substrate and be suitable for reducing or eliminating mechanical stress effects of a material layer on the front side of the substrate, or vice versa. The bending compensation layer can have comparable properties, such as the same material selection and dimensions, as a corresponding stress-compensated material layer on the other side of the substrate. Such a bending compensation layer can be easily produced by alternatingly processing the MEMS functional unit and the circuit unit on the front side and the rear side of the substrate, as described below. At the same time, the bending compensation layer can form a mechanical protective layer of the MEMS component during certain production steps. Furthermore, the bending compensation improves the already increased long-term stability, according to the proposal, and ensures reliable functionality of the MEMS functional unit and the circuit unit. As an alternative or in addition to arranging the bending compensation layer on the substrate of the MEMS component, it is possible that a bending compensation layer is arranged on the cap of the MEMS component, in particular if the cap is designed as a purely or predominantly mechanical cap. The bending compensation layer can be applied temporarily and later at least partially removed again, for example if it is used as a mechanical protective layer in a layer structure on the substrate, or it can remain permanently on the MEMS component, in particular if the bending compensation layer is arranged on the cap.

The present disclosure also relates to a method for producing a MEMS component according to one of the features described above. According to an example embodiment, the method comprises the following subprocesses:

providing the substrate;

creating a first partial layer structure of the MEMS functional unit on the front side of the substrate;

creating the electrical connection structure through the substrate;

creating the electrical circuit unit on the rear side of the substrate; and

creating a second partial layer structure on the first partial layer structure of the MEMS functional unit.

The example method of the present disclosure allows the described MEMS component of the present disclosure to be produced in a simple and efficient manner. The MEMS functional unit and the circuit unit can be produced in particular by structuring the substrate and/or by successively arranging and structuring material layers on the front side and the rear side of the substrate. Structuring can be carried out using an etching process, in particular a gas phase etching process. By alternatingly processing the MEMS functional unit and the circuit unit on the two sides of the substrate, different process conditions can be applied during the creation of the MEMS functional unit and of the circuit unit. For example, it is also possible to use high-temperature processes in the production of the MEMS functional unit since these processes can be used before the temperature-sensitive electrical structures of the circuit unit are applied. Furthermore, the intermediate substrate provides protection. High-temperature processes can, for example, be carried out at process temperatures above 800°C. Other monolithic structure and production concepts often involve producing the circuit unit first, which can restrict the subsequent production of the MEMS functional unit in terms of temperature. For example, in these cases, a certain maximum temperature should not be exceeded and some materials used may not be optimally designed for the intended function. Accordingly, the described order of processing the MEMS functional unit and the circuit unit in the proposed method offers particular advantages for the design and production of the MEMS component. The alternating processing of the MEMS functional unit and the circuit unit makes it possible to use high-temperature processes and promotes optimal layer structure.

Between the aforementioned creation subprocesses on the front side and the rear side of the substrate, the MEMS component can be rotated in order to allow for alternating processing on the front side and the rear side of the substrate. A subprocess can contain a plurality of process steps, which may include, for example, structuring the substrate, successively applying and structuring material layers, and/or an etching process.

According to one example embodiment, an insulating layer can be created on the electrical circuit unit according to a further subprocess. This further subprocess can be carried out in particular after the electrical circuit unit has been created on the rear side of the substrate. This allows the insulating layer to provide mechanical protection for the circuit unit even during the creation of the second partial layer structure on the first partial layer structure of the MEMS functional unit.

According to one example embodiment, an electrical connection structure can be created in and/or on the insulating layer according to a further subprocess. This further subprocess can be carried out in particular after the creation of the second partial layer structure on the first partial layer structure of the MEMS functional unit. The insulating layer can optionally be back-thinned or completely removed and replaced by a new insulating layer before the electrical connection structure is created. Creating the electrical connection structure may comprise introducing one or more vertical electrical connections to the circuit unit through the insulating layer. Creating the electrical connection structure may comprise applying one or more solder balls to the insulating layer at positions of vertical electrical connections.

According to one example embodiment, a side frame and a cap can be arranged on the front side of the substrate according to a further subprocess. The cap can be provided by providing a further substrate, in particular a silicon wafer. In particular, the cap can have a purely mechanical or predominantly mechanical function and be designed to be correspondingly robust. The cap can be configured in particular to seal a cavity of the MEMS component in a gas-tight manner when a gas or gas mixture at a predefined internal pressure is enclosed in the cavity. The side frame can be created by structuring the substrate and/or the further substrate. According to one possible embodiment, a part of the side frame can in each case be created by structuring the substrate and the further substrate, and the two parts of the side frame can be arranged on each other and connected to each other by a wafer bond connection. The wafer bond connection can, for example, be based on a eutectic aluminum-germanium connection. Arranging the cap on the front side of the substrate can follow the subprocess of creating a second partial layer structure on the first partial layer structure of the MEMS functional unit. Creating the side frame precedes arranging the cap on the front side of the substrate. If required, an access channel for a fluidic connection of the cavity to an environment of the MEMS component can be incorporated into the side frame and/or into the cap.

According to one example embodiment, creating the first partial layer structure of the MEMS functional unit can comprise creating a support structure and an electrical connection structure of the MEMS functional unit, and creating the second partial layer structure can comprise creating a MEMS functional element. Accordingly, a microelectromechanical substructure of the MEMS functional unit can be produced in a first creation subprocess, the circuit unit can be produced in a subsequent second creation subprocess, and the MEMS functional element intended for performing the function directly can be produced in a subsequent third creation subprocess. By sequentially producing the MEMS functional unit in separate subprocesses, the MEMS functional unit and the circuit unit on the two sides of the same substrate can be efficiently processed using high-temperature processes and robust standard materials. In particular, this order ensures that potentially temperature-sensitive structures of the circuit unit are applied after the high-temperature processes of the substructure of the MEMS functional unit and therefore cannot be damaged in high-temperature processes. The MEMS functional element can, for example, be a sensor element for detecting a force or environmental condition acting on the MEMS functional element.

An example of a MEMS functional element is a movable membrane, which can be designed, for example, for a pressure-dependent deflection, which can inter alia be detected using capacitive detection principles. Another example of a MEMS functional element is a seismic mass that can be displaced or pivoted under the influence of an acceleration force.

According to one example embodiment, a bending compensation layer can be arranged on the front side and/or on the rear side of the substrate and/or on the cap according to at least one further subprocess. This can reduce mechanical stress in the MEMS component, which can be caused, for example, by high-temperature processes and/or materials with different coefficients of expansion. Bending compensation for a material layer or a partial layer structure arranged on the front side of the substrate can be achieved, for example, by arranging a comparable compensation layer or a comparable compensation layer structure on the rear side of the substrate, and vice versa, since this can eliminate or at least reduce mechanical stress effects on the two sides of the substrate. Due to the proposed alternating processing of the MEMS functional unit and the circuit unit on the front side and the rear side of the substrate, such bending compensation can be easily implemented. Furthermore, the bending compensation improves the already increased long-term stability according to the proposal and ensures reliable functionality of the MEMS functional unit and the circuit unit. If a cap with a purely mechanical or predominantly mechanical function is used, a bending compensation layer can also be used in the cap. This layer would affect the entire MEMS component as soon as the cap is connected to the substrate. By designing the cap as a purely or predominantly mechanical cap, a bending compensation layer can be applied to the front side or to the rear side of the cap in a planar, in particular unstructured, manner, without having to take sensitive electrical structures into account.

In the context of the present disclosure, unless explicitly defined otherwise, the words "a/an" are generally not to be understood as a numeral, but as indefinite articles meaning "at least one."

The present disclosure allows for various embodiments and is explained in more detail below using an exemplary embodiment with the figures.

### BRIEF DESCRIPTION OF THE DRAWINGS

FIG. 1 shows a MEMS component according to an exemplary embodiment of the present disclosure in a side sectional view.

FIG. 2-7 show intermediate states of the MEMS component shown in FIG. 1, during its production.

FIG. 8 shows a method for producing the MEMS component shown in FIG. 1 and 2, according to an exemplary embodiment of the present disclosure.

### DETAILED DESCRIPTION OF EXAMPLE EMBODIMENTS

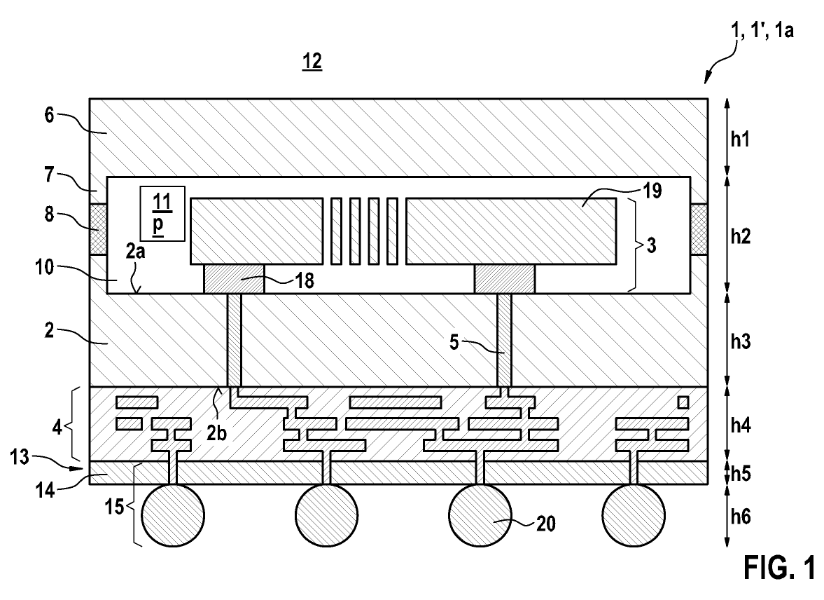

FIG. 1 shows a MEMS component 1, which can be designed as a sensor component 1', in particular as an inertial sensor component 1a, according to the exemplary embodiment shown. The MEMS component 1 has a substrate 2 with a front side 2a and a rear side 2b. A MEMS functional unit 3 with a support structure 18, an electrical connection structure (not shown in detail), and a MEMS functional element 19 is arranged on the front side 2a of the substrate 2. The MEMS functional element 19 can, for example, comprise a seismic mass for detecting an acceleration force acting on the MEMS component 1.

An electrical circuit unit 4 is arranged on the rear side 2b of the substrate 2. The electrical circuit unit 4 is configured to apply, receive and/or process signals of the MEMS functional unit 3 and contains specified evaluation and control electronics of the MEMS component 1. The circuit unit 4 can be designed, as schematically indicated in FIG. 1, in particular as an integrated circuit with a plurality of circuit planes.

An electrical connection structure 5 extends through the substrate 2 and can comprise a plurality of vertical TSV connections, as shown schematically in FIG. 1. The electrical connection structure 5 serves to electrically connect the MEMS functional unit 3 to the electrical circuit unit 4.

By monolithically forming the MEMS functional unit 3 and the circuit unit 4 on different sides of the substrate 2 with a via through the substrate 2, a particularly compact MEMS component 1 can be provided. Furthermore, it can be produced in a simple and efficient manner, as described below in connection with a method 100 for producing the MEMS component 1.

The MEMS component 1 also comprises a cap 6 and a side frame 7, which, together with the substrate 2, enclose a cavity 10, in which the MEMS functional unit 3 is arranged. According to the exemplary embodiment shown, a gas or gas mixture 11 at a predefined internal pressure p is enclosed in the cavity 10. According to an alternative possible embodiment, an access channel for a fluidic connection of the cavity 10 to an environment 12 of the MEMS component 1 can be arranged in the cap 6 and/or in the side frame 7, for example if the MEMS component 1 is designed as an environmental sensor component. The cap 6 and the substrate 2 are connected to each other in the region of the side frame 7 via a wafer bond connection 8, which can be designed in particular as a eutectic aluminum-germanium bond connection.

FIG. 1 shows that an insulating layer 14 with an electrical connection structure 15 is arranged on a side 13 of the electrical circuit unit 4 facing away from the substrate 2. The electrical connection structure 15, with a plurality of conductor tracks, can extend vertically through the insulating layer 14 as shown and can transition into solder balls 20.

For illustrating a possible dimensioning of the MEMS component 1, structure and layer heights h1 to h6 are shown in FIG. 1, for which non-restrictive value examples are given below. For example, a height h1 of the cap 6 can be 80 to 120 µm, in particular approximately 100 µm. A height h2 of the cavity 10, corresponding here to a height h2 of the side frame 7, can be 80 to 120 µm, in particular approximately 100 µm. A height h3 of the electrical connection structure 5 can be at least 300 µm. A height h4 of the electrical switching unit h4 can be between 5 and 15 µm, in particular approximately 10 µm. A height h5 of the insulating layer 14 can be between 1 and 3 µm, in particular approximately 2 µm. A height h6 of the solder balls 20 can be between 130 and 170 µm, in particular approximately 150 µm.

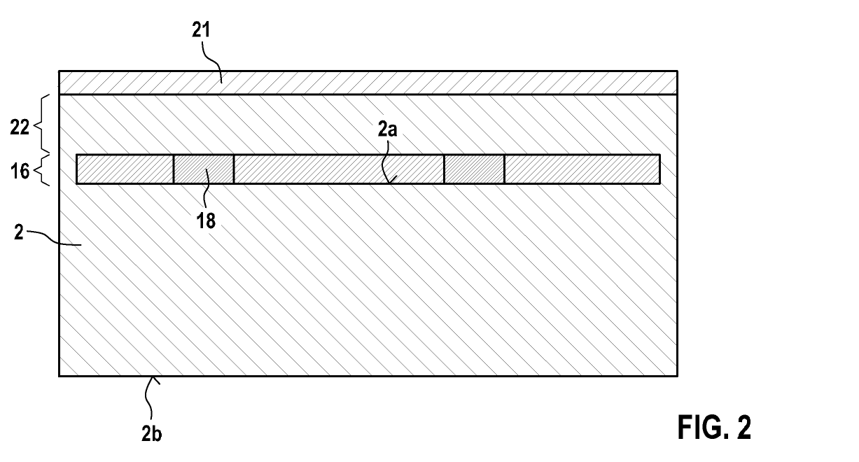

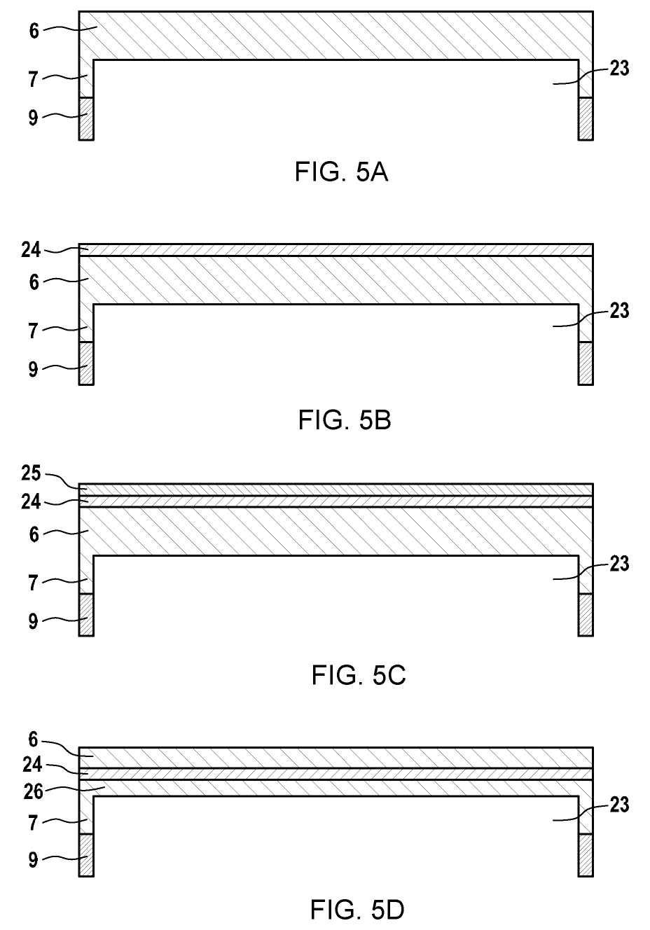

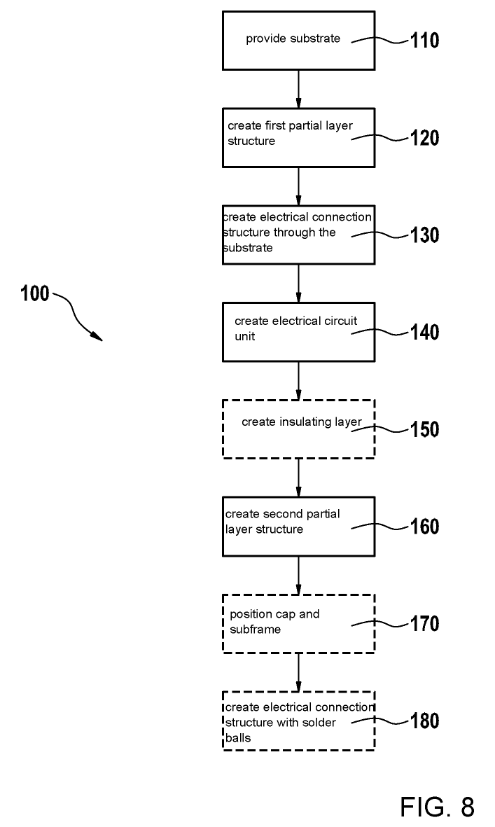

FIG. 2 to 7 show intermediate states of the MEMS component 1 shown in FIG. 1, during its production according to a method 100 illustrated in FIG. 8 by means of a schematic flowchart. FIG. 5A to 5D illustrate different variants of a cap 6 of the MEMS component 1. The method 100 allows the MEMS component 1 to be produced in a simple and efficient manner using standard materials and high-temperature processes. First, a silicon wafer is provided as the substrate 2 according to a subprocess 110. Alignment marks can be applied to the substrate 2 for the further processing. According to a further subprocess 120, a first partial layer structure 16 of the MEMS functional unit 3 with the support structure 18 and an electrical connection structure (not shown in detail) is created on the front side 2a of the substrate 2. High-temperature processes can be used in this case. The electrical connection structure can comprise, for example, wiring and insulation planes. The substrate 2 with the first partial layer structure 16 is shown in FIG. 2. On the first partial layer structure 16, a silicon layer 22 is arranged, from which the MEMS functional element 19 is later released. For example, a protective layer 21 is applied to the silicon layer 22 using a PECVD process and ensures mechanical protection of the silicon layer 22 and the partial layer structure 16 during the following subprocesses. The protective layer 21 can, for example, be a sacrificial layer made of silicon oxide. The protective layer 21 can be stress-optimized, for example by designing the protective layer 21 as a compensation layer in order to achieve bending compensation on the front side 2a of the substrate 2.

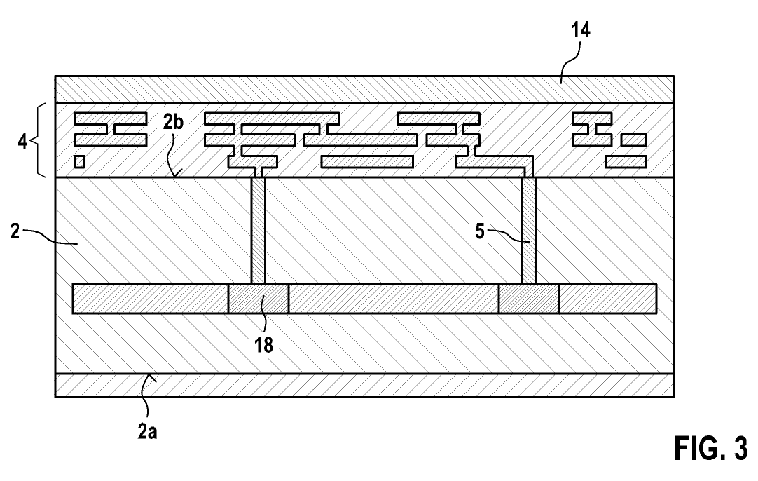

As illustrated in FIG. 3, the layer structure produced in this way can be rotated with the substrate 2 for the next subprocesses. According to a further subprocess 130, the electrical connection structure 5 through the substrate 2 is created by producing vertical TSV connections in the substrate 2. According to a further subprocess 140, the electrical circuit unit 4 is subsequently created on the rear side 2b of the substrate 2. For this purpose, a plurality of circuit planes, including a front-end plane and a back-end plane, can be created successively. As shown in FIG. 3, an insulating layer 14 is created on the electrical circuit unit 4 according to a further subprocess 150. This insulating layer is initially designed to be as robust as possible in order to protect the circuit unit 4 during the further subprocesses and to simplify the handling of the MEMS component 1. Furthermore, the insulating layer 14 ensures electrical isolation of the circuit unit 4 from the environment 12 of the MEMS component 1. The insulating layer 14 can be stress-optimized, for example by designing the insulating layer 14 as a compensation layer in order to achieve bending compensation on the rear side 2b of the substrate 2.

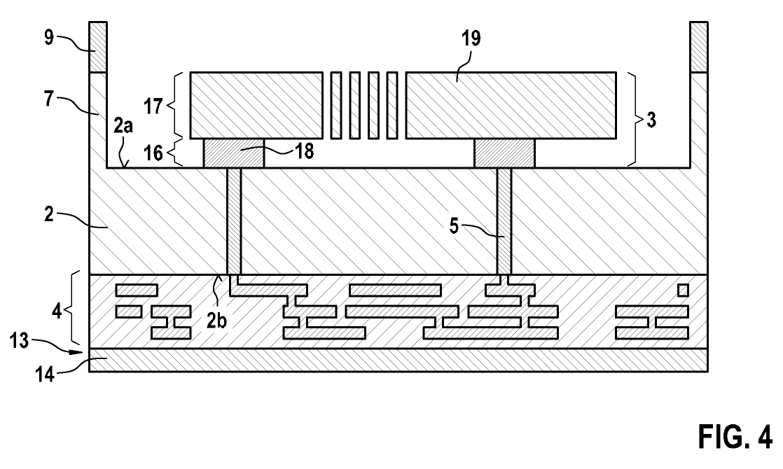

As illustrated in FIG. 4, the layer structure produced in this way can be rotated with the substrate 2 for the next subprocesses. First, the protective layer 21 can be removed, for example by grinding and polishing or by back-etching, until a smooth surface of the silicon layer 22 is exposed. A bond connection material 9, such as a metal, semimetal, or semiconductor, in particular aluminum or germanium, can be deposited on this surface in order to prepare for the later wafer bonding connection 8. The bond connection material 9 can subsequently be structured by means of lithography and etching processes, as shown in FIG. 4. According to a further subprocess 160, a second partial layer structure 17 is created on the first partial layer structure 16 of the MEMS functional unit 3 by releasing the MEMS functional element 19 from the silicon layer 22, for example by gas phase etching. Furthermore, part of the side frame 7 is created through structuring.

FIG. 5A to 5D show a prepared cap 6 with a part of a side frame 7, which are made from a further silicon wafer. According to one possible embodiment, the further silicon wafer can be back-thinned, a bond connection material 9 can be deposited, for example a metal, semimetal, or semiconductor, in particular aluminum or germanium, and the silicon wafer and the bond connection material 9 can be structured by means of lithography and etching processes as shown in FIG. 5A to 5D. Optionally, for enlarging the cavity 10, a recess 23 can be etched into the cap 6, for example by means of a trenching process. FIG. 5A first shows a simple variant of the cap 6 with the side frame 7, the bond connection material 9, and the recess 23 for enlarging the cavity 10. FIG. 5B illustrates, according to a variant of the cap 6, that a bending compensation layer 24, which can effectively reduce mechanical stress of the MEMS component 1, is arranged on the cap 6. The bending compensation layer 24 can, for example, be applied to the rear side of the cap 6 after it has been back-thinned, which is efficient in terms of process technology since only a single additional planar deposition is required. According to the further variant of the cap 6 shown in FIG. 5C, a supplementary cap protection layer 25 can be applied to the bending compensation layer 24 with little additional effort by means of a further deposition in order to largely protect the bending compensation layer 24 from external influences. FIG. 5D illustrates a further variant of the cap 6 for a possible embodiment of the method 100, in which back-thinning of the cap 6 is only provided after the bonding process described below for connecting the cap 6 to the substrate 2. In this process, the bending compensation layer 24 is embedded into the material of the cap 6, for example between a silicon-based separating layer 26 between the bending compensation layer 24 and the recess 23 and the actual cap 6. If the bending compensation layer 24 is made of a non-outgassing material or if a predictable outgassing behavior can be compensated by a suitable internal pressure setting, the separating layer 26 can also be omitted.

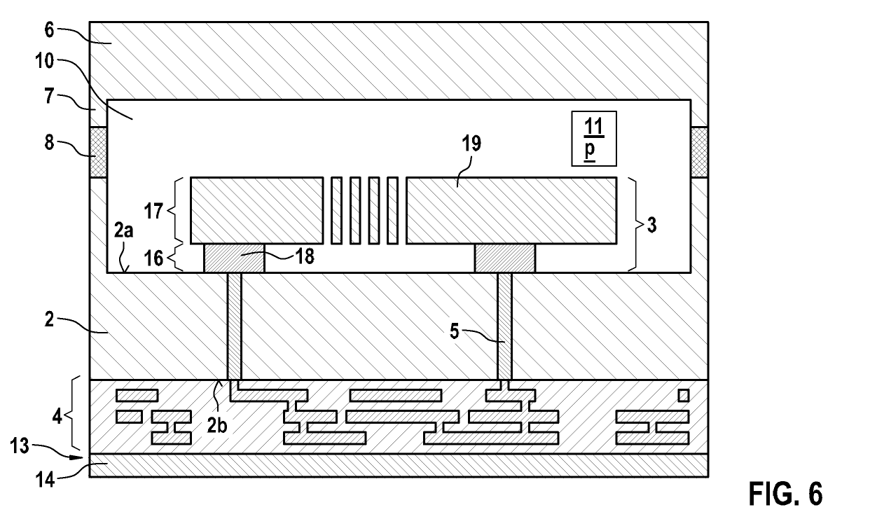

According to a further subprocess 170, as can be seen in FIG. 6, the cap 6, here a cap 6 according to the exemplary embodiment shown in FIG. 5A, and the side frame 7 are positioned on the front side 2a of the substrate and connected to the substrate 2 by a eutectic bonding process in the region of the side frame 7 and the bond connection materials 9 contacting one another there, in order to form a hermetically sealed cavity 10. In this process, a gas or a gas mixture 11 at a predefined internal pressure p can be enclosed in the cavity 10.

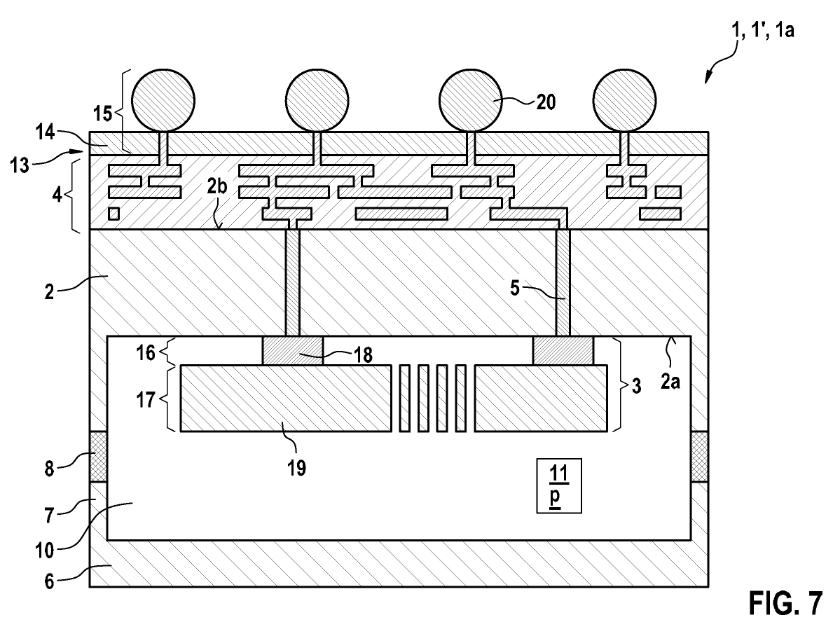

The MEMS component 1 can subsequently be rotated again, as illustrated in FIG. 7. According to a further subprocess 180, an electrical connection structure 15 with solder balls 20 is then created in and on the insulating layer 14. For this purpose, the insulating layer 14 can, if necessary, first be back-etched or back-ground in order to remove defects in the insulating layer 14 from previous subprocesses. Subsequently, a thin new passivation can be applied and the insulating layer 14 can be opened in order to route the electrical contacts to the circuit unit 4 to the outside. Afterwards, the solder balls 20 can be arranged on the electrical contacts.

According to one possible embodiment, a peripheral, for example metal, protective ring can additionally be incorporated into the circuit unit 4 in order to protect the circuit unit 4 from moisture.

What is claimed is:

1. A microelectromechanical system (MEMS) component, comprising:
a substrate with a front side and a rear side;
a MEMS functional unit arranged on the front side of the substrate;
an electrical circuit unit arranged on the rear side of the substrate for applying and/or receiving and/or processing signals of the MEMS functional unit; and
an electrical connection structure extending through the substrate, for electrically connecting the MEMS functional unit to the electrical circuit unit.

2. The MEMS component according to claim 1, wherein the MEMS component further comprises a cap and a side frame, which, together with the substrate, enclose a cavity in which the MEMS functional unit is arranged.

3. The MEMS component according to claim 2, wherein a gas or gas mixture at a predefined internal pressure is enclosed in the cavity.

4. The MEMS component according to claim 2, wherein an access channel for a fluidic connection of the cavity to an environment of the MEMS component is arranged in the cap and/or in the side frame.

5. The MEMS component according to claim 1, wherein an insulating layer with an electrical connection structure is arranged on a side of the electrical circuit unit facing away from the substrate.

6. The MEMS component according to claim 1, wherein the MEMS component is configured as a sensor component.

7. The MEMS component according to claim 6, wherein the MEMS component is configured as an inertial sensor component.

8. The MEMS component according to claim 6, wherein the MEMS component is configured as an environmental sensor component.

9. The MEMS component according to claim 1, wherein the MEMS component includes a bending compensation layer.

10. A method for producing a microelectromechanical system (MEMS) component, the MEMS component including:
a substrate with a front side and a rear side,
a MEMS functional unit arranged on the front side of the substrate,
an electrical circuit unit arranged on the rear side of the substrate for applying and/or receiving and/or processing signals of the MEMS functional unit, and
an electrical connection structure extending through the substrate, for electrically connecting the MEMS functional unit to the electrical circuit unit,
wherein the method comprises the following subprocesses:
providing the substrate;
creating a first partial layer structure of the MEMS functional unit on the front side of the substrate;
creating the electrical connection structure through the substrate;
creating the electrical circuit unit on the rear side of the substrate; and
creating a second partial layer structure on the first partial layer structure of the MEMS functional unit.

11. The method according to claim 10, wherein an insulating layer is created on the electrical circuit unit according to a further subprocess.

12. The method according to claim 11, wherein an electrical connection structure is created in and/or on the insulating layer according to a further subprocess.

13. The method according to claim 10, wherein a side frame and a cap are arranged on the front side of the substrate according to a further subprocess.

14. The method according to claim 10, wherein the creating of the first partial layer structure of the MEMS functional unit includes creating a support structure and an electrical connection structure of the MEMS functional unit, and wherein the creating of the second partial layer structure includes creating a MEMS functional element.

15. The method according to claim 13, wherein a bending compensation layer is arranged: (i) on the front side and/or on the rear side of the substrate and/or (ii) on the cap according to at least one further subprocess.
